(19) United States
(12) Patent Application Publication
(10) Pub. No.: US 2024/0021728 A1
(43) Pub. Date: Jan. 18, 2024

(54) SEMICONDUCTOR STRUCTURE AND FABRICATION METHOD THEREOF

(71) Applicant: Semiconductor Manufacturing South China Corporation, Shanghai (CN)

(72) Inventors: Zhenhui YANG, Shanghai (CN); Guangzhou XU, Shanghai (CN); Zhao LI, Shanghai (CN); Hongjuan LI, Shanghai (CN)

(21) Appl. No.: 18/038,882

(22) PCT Filed: Nov. 27, 2020
(86) PCT No.: PCT/CN2020/132129

§ 371 Date: May 25, 2023

(51) Int. Cl. H01L 29/78; H01L 29/66; H01L 29/06; H01L 21/311

(52) U.S. Cl. CPC H01L 29/785; H01L 29/66795; H01L 29/66545; H01L 29/0684; H01L 21/31116; H01L 21/31144

(57) ABSTRACT

A semiconductor structure and a method for forming semiconductor structure are provided. The semiconductor structure includes a substrate and a dielectric layer on the substrate, the dielectric layer containing gate openings. Each gate opening includes a first region and a second region on the first region. The first region has a first projection on the substrate, the second region has a second projection on the substrate. An area of the second projection is larger than an area of the first projection, and the first projection is located within the second projection. A gate layer is located in each first region and one corresponding second region.

### TECHNICAL FIELD

The present disclosure generally relates to the field of semiconductor fabrication technology and, more particularly, relates to a semiconductor structure and a fabrication method thereof.

### BACKGROUND

The semiconductor integrated circuit (IC) industry has experienced exponential growth. In the process of IC evolution, functional density (that is, the number of interconnected devices per chip area) has generally increased, while geometry size (that is, the smallest component or line that can be produced using a fabrication process) has decreased. This scaling down process generally provides benefits by increasing production efficiency and reducing associated costs. This scaling down also increases the complexity of handling and manufacturing the ICs.

In some IC designs, as technology nodes shrink, a realized advantage is, by replacing typical polysilicon gates with metal gates to improve device performance as the feature size shrinks. One process for forming the metal gates is known as a replacement gate process or a “gate last” process, in which the metal gates are fabricated “last”. This allows for a reduction in the number of subsequent processes, including the high temperature processing that need to be performed after the gates are formed.

However, there are still some problems in the existing “gate-last” process for forming the metal gates.

### SUMMARY

The preset disclosure provides a semiconductor structure and a method for forming a semiconductor structure, to improve the performance of the formed semiconductor structure.

To solve the above technical problems, the present disclosure provides a semiconductor structure. The semiconductor structure includes: a substrate; a dielectric layer on the substrate; gate openings in the dielectric layer, where each gate opening includes a first region and a second region on the first region, the first region has a first projection on the substrate, the second region has a second projection on the substrate, an area of the second projection is larger than an area of the first projection, and the first projection is located within the second projection; and a gate layer in each first region and one corresponding second region.

Optionally, a range by which a size of the second region in a first direction parallel to a surface of the substrate is larger than a size of the first region in the first direction parallel to the surface of the substrate is about 1-5 nm.

Optionally, the gate opening further includes a third region on the second region, the third region has a third projection on the substrate, an area of the third projection is larger than the area of the second projection, and the second projection and the first projection are located within the third projection.

Optionally, a range by which a size of the third region in the first direction parallel to the surface of the substrate is larger than the size of the second region in the first direction parallel to the surface of the substrate is about 1-5 nm.

Optionally, the semiconductor structure further includes a barrier layer in each third region.

Optionally, the barrier layer is made of a material including a dielectric material, and the dielectric material includes silicon nitride.

Optionally, the semiconductor structure further includes a gate dielectric layer on sidewall surfaces and bottom surfaces of each first region, and a work function layer on the gate dielectric layer, wherein the gate layer is located on the work function layer.

Optionally, the semiconductor structure further includes source/drain doped layers in the substrate at two sides of each gate layer.

Optionally, the substrate includes a base substrate and fin structures on the base substrate; the gate openings expose a portion of top surfaces and sidewall surfaces of the fin structures; the gate layers cross the fin structures; and the first direction is an extending direction of the fin structures.

Optionally, a top surface of the first region is higher than or coplanar with the top surfaces of the fin structures.

Optionally, the gate layer is made by a material including a metal and the metal includes tungsten.

Correspondingly, he present disclosure provides a method for forming a semiconductor structure. The method includes: providing a substrate; forming dummy gate structures on the substrate; forming a dielectric layer on sidewalls of the dummy gate structures; removing the dummy gate structures to form initial gate openings, such that each initial gate opening includes a first region and an initial second region on the first region, and the first region has a first projection on the substrate; removing a portion of the dielectric layer on sidewalls of each second region to form a gate opening, such that the gate opening includes the first region and a second region on the first region, the first region has a first projection on the substrate, the second region has a second projection on the substrate, an area of the second projection is larger than an area of the first projection, and the first projection is located within the second projection; and forming an initial gate layer in each gate opening.

Optionally, a range by which a size of the second region in a first direction parallel to a surface of the substrate is larger than a size of the first region in the first direction parallel to the surface of the substrate is about 1-5 nm.

Optionally, the second region is formed by: forming a sacrificial layer in each first region; using sacrificial layer as a mask to etch the dielectric layer on the sidewalls of the initial second region, to form the second region; and after forming the second region, removing the sacrificial layer.

Optionally, the sacrificial layer is formed by: forming a sacrificial material layer in the initial gate openings and on the dielectric layer; and etching back the sacrificial material layer until exposing the initial second regions, to form one sacrificial layer in each first region.

Optionally, the sacrificial layer is made of an organic material and the organic material includes amorphous silicon or photoresist.

Optionally, the dielectric layer on the sidewalls of the initial second region is etched by an isotropic dry etching method.

Optionally, before forming the sacrificial layer in the first region, the method further includes: forming an initial gate dielectric layer on the sidewall surfaces and the bottom surface of the initial gate opening and an initial work function layer on the initial gate dielectric layer, wherein the sacrificial layer is located on the initial work function layer.

Optionally, before using the sacrificial layer as the mask to etch the dielectric layer on the sidewalls of the initial second region, the method further includes: using the sacrificial layer as a mask to remove the initial gate dielectric layer and the initial function layer on the sidewalls of the initial second region, to form the gate dielectric layer and the work function layer on the sidewall surfaces and the bottom surfaces of the first region, such that the second region exposes the top surface of the gate dielectric layer and the top surface of the work function layer.

Optionally, the initial gate dielectric layer and the initial function layer on the sidewalls of the initial second region are removed by a wet etching method.

Optionally, a depth-to-width aspect ratio of each initial gate opening is about 3˜6.

Optionally, the initial gate layers are formed by: forming a gate material layer in the gate openings and on the dielectric layer; and planarizing the gate material layer until exposing the surface of the dielectric layer, to form the initial gate layers.

Optionally, the gate material layer is formed by a physical vapor deposition method.

Optionally, each gate opening further includes a third region on the corresponding second region.

Optionally, the third regions are formed by: removing a portion of the initial gate layer to form the gate layer and transition third regions in the dielectric layer, such that the sidewalls of the transition third regions expose the dielectric layer; and etching the dielectric layer exposed by the sidewalls of the transition third regions to form third regions. Each third region has a third projection on the substrate, an area of the third projection is larger than the area of the second projection, and the second projection and the first projection are located within the third projection.

Optionally, the dielectric layer exposed by the sidewalls of the transition third regions is etched by a method including an isotropic dry etching method.

Optionally, a range by which a size of the third region in the first direction parallel to the surface of the substrate is larger than the size of the second region in the first direction parallel to the surface of the substrate is about 1-5 nm.

Optionally, before forming the dielectric layer on the sidewalls of the dummy gate structures, the method further includes: forming source/drain doped regions in the substrate at two sides of each dummy gate structure.

Optionally, the method further includes: forming a barrier layer in each third region; and after forming the barrier layer in the third region, forming conductive plugs in the dielectric layer, wherein the conductive plugs are located on the source/drain doped regions.

Optionally, the substrate includes a base substrate and fin structures on the base substrate; the gate openings expose a portion of top surfaces and sidewall surfaces of the fin structures; the gate layers cross the fin structures; and the first direction is an extending direction of the fin structures.

Optionally, a top surface of the first region is higher than or flush with the top surfaces of the fin structures.

Optionally, the gate layer is made of a material including metal and the metal includes tungsten.

In comparison to the existing technology, the present disclosure has following advantages.

In the semiconductor structure provided by the present disclosure, the semiconductor structure includes the gate openings located in the dielectric layer. Each gate opening includes a first region and a second region located on the first region. The first region has a first projection on the substrate, and the second region has a second projection on the substrate. The area of the second projection is larger than that of the first projection, and the first projection is within the range of the second projection. Therefore, when forming the gate layer in the first region and the second region, the material of the gate layer is easily filled into the first region, thereby making the formed gate layer structure dense and being beneficial to improving the reliability of the semiconductor structure.

Further, the gate opening further includes the third region on the second region. The third region has a third projection on the substrate, and the area of the third projection is larger than the area of the second projection. The second projection and the first projection are within the range of the third projection. The barrier layer is located in the third region. Therefore, when the conductive plugs located on the source/drain doped regions are subsequently formed, the barrier layer may be able to limit the conductive plugs, thereby reducing the occurrence of the short circuit because of the contact between the conductive plugs and the gate layers in the first regions and the gate layers in the second regions, thereby improving the performance of the semiconductor structure.

In the method for forming the semiconductor structure provided by the present disclosure, by removing a portion of the dielectric layer on the sidewalls of the initial second regions, in each formed gate opening, the area of the second projection is larger than that of the first projection of the first region. Therefore, when forming the initial gate layer in the first region and the second region, the material of the initial gate layer is easily filled into the first region, thereby making the formed initial gate layer structure dense and being beneficial to improving the reliability of the semiconductor structure.

Further, the gate opening further includes the third region on the second region. The third region has a third projection on the substrate, and the area of the third projection is larger than the area of the second projection. The second projection and the first projection are within the range of the third projection. The barrier layer is located in the third region. Therefore, when the conductive plugs located on the source/drain doped regions are subsequently formed, the barrier layer may be able to limit the conductive plugs, thereby reducing the occurrence of the short circuit because of the contact between the conductive plugs and the gate layers in the first regions and the gate layers in the second regions, thereby improving the performance of the semiconductor structure.

### BRIEF DESCRIPTION OF THE DRAWINGS

FIG. 1 illustrates a cross-sectional view of a semiconductor structure.

FIGS. 2-8 illustrate cross-sectional views of an exemplary semiconductor structure according to various disclosed embodiments of the present disclosure.

### DETAILED DESCRIPTION

As described in the background, there are still some problems in the existing “gate-last” process for forming the metal gates. It will be analyzed and described below in combination with an example.

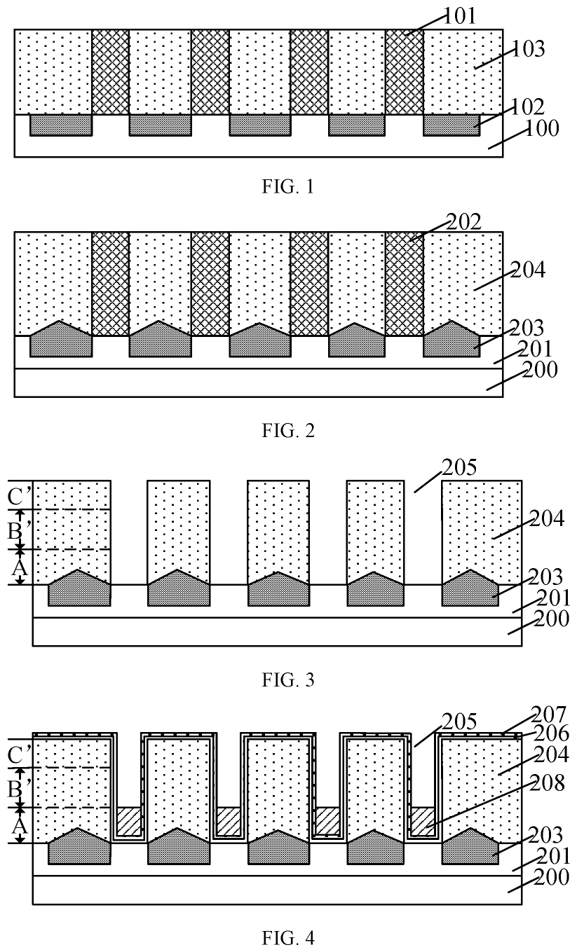

FIG. 1 illustrates a cross-sectional view of a semiconductor structure.

As shown in FIG. 1, the semiconductor structure includes a substrate 100, gate structures 101 on the substrate 100, source/drain doped regions 102 in the substrate 100 at two sides of each gate structure 101, and a dielectric layer 103 on the substrate 100. The dielectric layer 103 may be located on sidewalls of the gate structures 101.

The gate structures 101 are metal gates. It is necessary to form dummy gates first, and then form the dielectric layer 103 on sidewalls of the dummy gates. The dummy gates are removed subsequently to form gate openings in the dielectric layer 103. The gate structures 103 then are formed in the gate openings. Each gate structure includes a gate dielectric layer (not illustrated), a work function layer on the gate dielectric layer (not illustrated), and a gate layer on the work function layer (not illustrated). The gate layer is made of a material including tungsten metal. Because of a large aspect ratio of the gate opening, the gate dielectric layer and the work function layer are first formed in the gate opening. When the physical vapor deposition process is used to deposit a gate material layer, it is relatively difficult for the reaction gas of the physical vapor deposition process to reach the bottom of the gate opening. Therefore, it will preferentially deposit on the top of the gate opening to close the gate opening, such that the formed gate layer structure is loose and has holes. Therefore, the resistance of the formed gate structures 101 becomes larger and reliability deteriorates, adversely affecting the performance of the semiconductor structure.

Reducing the aspect ratio of the gate opening is able to solve the problem of poor material filling effect of the gate layer. However, when the width of the gate opening becomes larger, the distance between adjacent gate structures 101 is correspondingly reduced. When conductive plugs electrically connected to the source/drain doped regions 102 is subsequently formed in the dielectric layer 103, the conductive plugs are likely to be in contact with the gate structures 101 to cause a short circuit, which affects the performance of the semiconductor structure.

The present disclosure provides a semiconductor structure and its fabrication method, to at least partially alleviate the above problem. A portion of a dielectric layer on initial sidewalls of a second region may be removed, such that a second projection area of the second region of a formed gate opening is larger than a first projection area of a first region. Therefore, when forming an initial gate layer in the gate opening, it may be easy for the material of the initial gate layer to fill the first region. The formed initial gate layer may have a dense structure, to improve the reliability of the formed semiconductor structure.

Reference will now be made in detail to exemplary embodiments of the present disclosure, which are illustrated in the accompanying drawings.

FIGS. 2-8 illustrate cross-sectional views of an exemplary semiconductor structure according to various disclosed embodiments of the present disclosure.

As shown in FIG. 2, a substrate may be provided.

In one embodiment, the substrate may include a base substrate 200 and fin structures 201 on the base substrate. An isolation layer may be provided on the substrate. The isolation layer may be located on a portion of sidewalls of the fin structures 201, and a top surface of the isolation layer may be lower than top surfaces of the fin structures.

In one embodiment, the base substrate 200 may be made of a material including silicon, and the fin structures 201 may be made of a material including silicon.

In some other embodiments, the base substrate 200 may be made of a material including silicon carbonite, silicon germanite, multi-nary semiconductor materials consisting of III-V elements, silicon-on-insulator, or germanium-on-insulator. The multi-nary semiconductor materials consisting of III-V elements may include InP, GaAs, GaP, InAs, InSb, InGaAs, or InGaAsP. The fin structures 201 may be made of a material including silicon carbonite, silicon germanite, multi-nary semiconductor materials consisting of III-V elements, silicon-on-insulator, or germanium-on-insulator. The multi-nary semiconductor materials consisting of III-V elements may include InP, GaAs, GaP, InAs, InSb, InGaAs, or InGaAsP.

In one embodiment, an extending direction of the fin structures 201 may be a first direction parallel to a surface of the substrate.

In some other embodiments, the substrate may be a planar substrate.

As shown in FIG. 2, dummy gate structures 202 may be formed on the substrate, and source/drain doped regions 203 may be formed in the substrate at two sides of each dummy gate structure 202.

In one embodiment, the dummy gate structures 202 may cross the fin structures 201.

Each dummy gate structure 102 may include a dummy gate dielectric layer (not illustrated) and a dummy gate layer on the dummy gate dielectric layer (not illustrated).

The dummy gate dielectric layer may be made of a material including silicon oxide or a low-K material (with K smaller than 3.9). The dummy gate layer may be made of a material including polysilicon.

In one embodiment, the source/drain doped regions 203 may be formed by an epitaxial growth process. Top surfaces of the source/drain doped regions 203 may be higher than the top surfaces of the fin structures 201.

In other embodiments, the source/drain doped regions 203 may be formed by an ion implanting process. The top surfaces of the source/drain doped regions 203 may be flush with the top surfaces of the fin structures 201.

As shown in FIG. 2, a dielectric layer 204 may be formed on sidewalls of the dummy gate structures 202.

The dielectric layer 204 may be made of a dielectric material. The dielectric material may include silicon oxide, silicon nitride, silicon carbide, SiCO, SiNO, aluminum oxide, aluminum nitride, SiNO, SiNCO, or a combination thereof.

In one embodiment, the dielectric layer 204 may be made of a material including silicon oxide.

As shown in FIG. 3, the dummy gate structures 202 may be removed, to form initial gate openings 205 in the dielectric layer 204. Each initial gate opening 205 may include a first region A and an initial second region B′ on the first region A. The first region A may have a first projection on the substrate.

A top surface of the first region A may be higher than the top surfaces of the fin structures 201.

In one embodiment, the top surface of the first region A may be higher than the top surfaces of the fin structures 201. Therefore, when subsequently forming a gate layer in a second region, it may be difficult for the gate layer to contact the source/drain doped regions 203 and the fin structures 201, and the gate layer may be prevented from being in contact with the source/drain doped regions 203 and the fin structures 201 to avoid shorted circuits.

In one embodiment, each initial gate opening 205 may further include an initial third region C′ on the initial second region B′. The initial third region C′ may be used to form a third region and then a barrier layer may be formed in the third region.

In some other embodiment, the initial third region C′ may not be provided.

In one embodiment, a depth-width aspect ratio of the initial gate openings 205 may be about 3 to about 6.

Subsequently, a portion of the dielectric layer 204 on sidewalls of initial second region B′ may be removed, to form transient gate openings 211. Each transient gate opening 211 may include one first region A, a second region B on the first region A, and a transient third region C″ on the second region B. The second region B may have a second projection on the substrate, and an area of the second projection may be larger than an area of the first projection. The first projection may be located within the second projection. The process for forming the second region B is shown in FIG. 4 to FIG. 6.

As shown in FIG. 4, an initial gate dielectric layer 206 and an initial work function layer 207 may be formed on side surfaces and bottom surfaces of the initial gate openings 205.

The initial gate dielectric layer 206 may be used to provide a material layer for subsequently forming gate dielectric layers on side surfaces and bottom surfaces of the first regions A. The initial work function layer 207 may be used to provide a material layer for forming work function layers on the gate dielectric layers.

The initial gate dielectric layer 206 may be made of a material including a high dielectric constant material. The high dielectric constant material may be a material with a dielectric constant larger than 3.9, and may include aluminum oxide or hafnium oxide. The initial work function layer 207 may be made of a material including an N-type work function material or a P-type work function material. The N-type work function material may include AlTi. The P-type work function material may include TiN or TaN.

The initial gate dielectric layer 206 may be formed by a process including an atomic layer deposition method, a chemical vapor deposition method, or a heat treatment process. The initial work function layer 207 may be formed by a process including an atomic layer deposition method, a chemical vapor deposition method, or a heat treatment process.

In the present embodiment, the initial gate dielectric layer 206 may be formed by the atomic layer deposition method. The initial work function layer 207 may be formed by the atomic layer deposition method.

As shown in FIG. 4, a sacrificial layer 208 may be formed in each first region A. A top surface of the sacrificial layer 208 may be higher than or be flush with the top surfaces of the source/drain doped regions 203. The sacrificial layer 208 may be located on the initial work function layer 207.

In the present embodiment, the top surfaces of the sacrificial layers 208 may be higher than or be flush with the top surfaces of the source/drain doped regions 203. Therefore, the subsequently formed second region may be higher than or be flush with the top surfaces of the source/drain doped regions 203.

The sacrificial layers 208 may be formed by: forming a sacrificial material layer (not illustrated) in the initial gate openings 205 and on the dielectric layer 204; etching back the sacrificial material layer until exposing the initial second regions B′, to form the sacrificial layers 208 in the first regions A.

The sacrificial layers 208 may be made of an organic material. The organic material may include amorphous carbon or photoresist. The sacrificial material layer may be formed by a spin coating method.

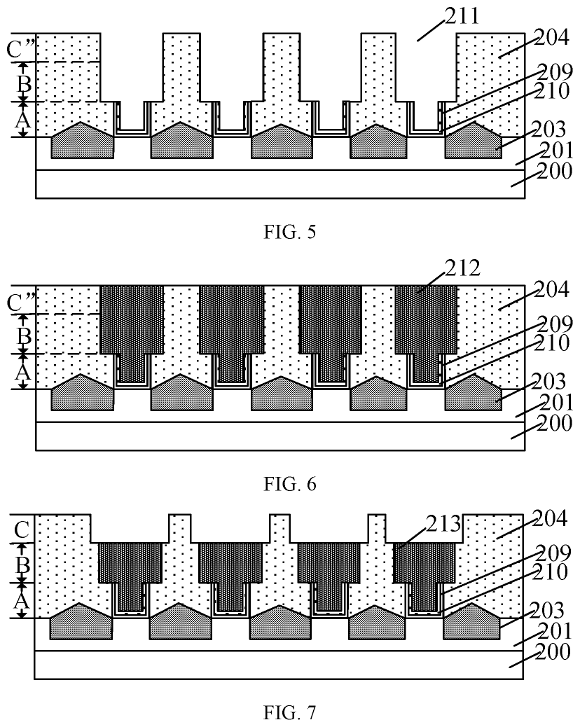

As shown in FIG. 5, a portion of the initial gate dielectric layer 206 and a portion of the initial work function layer 207 on sidewalls of the initial second region B′ and the initial third region C′ may be removed by using the sacrificial layers 208 as a mask, to form a gate dielectric layer 209 and a work function layer on the side surface and the bottom surface of each first region A.

The portion of the initial gate dielectric layer 206 and the portion of the initial work function layer 207 on sidewalls of the initial second region B′ and the initial third region C′ may be removed by a wet etching process or a dry etching process.

In the present embodiment, the portion of the initial gate dielectric layer 206 and the portion of the initial work function layer 207 on sidewalls of the initial second region B′ and the initial third region C′ may be removed by the wet etching process. The wet etching process may be able to completely remove the portion of the initial gate dielectric layer 206 and the portion of the initial work function layer 207 on sidewalls of the initial second region B′ and the initial third region C′ may be removed by a wet etching process, such that barriers to the etching process for subsequently etching the dielectric layer 204 on the sidewalls of the initial second regions B′ may be small and the second regions B with a good profile may be obtained.

As shown in FIG. 5, the dielectric layer 204 on the sidewalls of the initial second regions B′ and the initial third regions C′ may be etched by using the sacrificial layers 206 as a mask, to form transient gate openings 211. Each transient gate opening 211 may include a second region B and a transient third region C″ on the second region B. The second region B may expose a top surface of a corresponding gate dielectric layer 209 and a top surface of a corresponding work function layer 210.

In this embodiment, the second region B may have the second projection on the substrate. The area of the second projection may be larger than the area of the first projection, and the first projection may be located within the range of the second projection. Therefore, when the initial gate layers are subsequently formed in the transition gate openings 211, the material of the initial gate layers may be easily filled into the first regions A, such that the formed initial gate layers may have a dense structure, to improve the reliability of the semiconductor structure.

A size difference between the size of the second region B in the first direction and the size of the first region A in the first direction may range from 1 nm to 5 nm. This range at which the second region B is larger than the size of the first region A may make the gate material be easily filled at the bottoms of the first regions A when the gate material is filled in the second regions B and the first regions A, such that the subsequently formed gate layers may have a compact structure and better performance.

The dielectric layer 204 on the sidewalls of the initial second regions B′ may be etched by an isotropic dry etching process. The etching direction selectivity of the isotropic dry etching process is good, such that the dielectric layer 204 on the sidewalls of the initial second regions B′ and the initial third regions C′ may be laterally etched to form the second regions B having the area of the second projection larger than the area of the first projection.

After forming the second regions B, the sacrificial layers 208 may be removed.

The sacrificial layers 208 may be removed by a dry etching method or a wet etching method.

As shown in FIG. 6, an initial gate layer 212 may be formed in each transition gate opening 211.

The initial gate layers 212 may be formed by: forming a gate material layer (not illustrated) in the transition gate openings 211 and on the dielectric layer 204; and planarizing the gate material layer until exposing the surface of the dielectric layer 204, to form the initial gate layers 212.

In one embodiment, the gate material layer may be formed by a physical vapor deposition method. The physical vapor deposition method may be able to quickly form the gate material layer with a dense structure and large thickness.

The initial gate layers 212 may be made of a material including a metal and the metal may include tungsten.

Since the area of the second projection of the second region B in one transition gate opening 211 is larger than the area of the first projection of the first region A, the material of the initial gate layer 212 may be easily filled into the first region A when forming the initial gate layer 212 in the transition gate opening 211. Therefore, the formed initial gate layer 212 may have a dense structure and the reliability of the semiconductor structure may be improved.

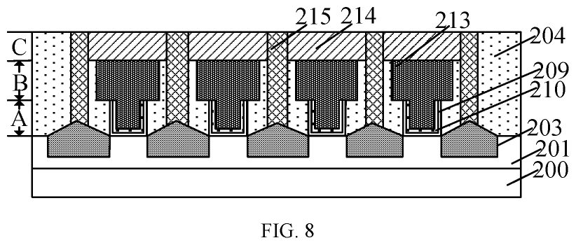

Subsequently, the gate layers may be formed in the first regions A and the second regions B, and the third regions C may be formed on the second regions B. The formation of the third regions C may be made reference to FIG. 7 and FIG. 8.

As shown in FIG. 7, a portion of each initial gate layer 212 may be removed to form a gate opening (not illustrated). Each gate opening may include one corresponding region A, one corresponding second region B, and one corresponding third region C on the corresponding second region B. A gate layer 213 may be formed in the first region A and the second region B of each gate opening. The gate layer 213 may expose one corresponding transition third region C″ and the sidewalls of the corresponding transition third region C″ may expose the dielectric layer 204.

The portion of the initial gate layer 212 may be removed by a dry etching method or a wet etching method.

As shown in FIG. 7, the dielectric layer 204 exposed by the transition third regions C″ may be etched, to form third regions C. Each third region C may have a third projection on the substrate, and an area of the third projection may be larger than the area of the second projection. The second projection and the first projection may be located in the third projection.

The dielectric layer exposed by the transition third regions C″ may be etched by an isotropic dry etching method. The etching direction selectivity of the isotropic dry etching method is good, such that the dielectric layer 204 on the sidewalls of the transition third regions C″ may be laterally etched to form the third regions C with the area of the third projection larger than the area of the first projection and the area of the second projection.

A range by which the size of the third regions C in the first direction is larger than the size of the second regions B in the first direction may be about 1 nm to 5 nm. When the range by which the size of the third regions is larger than the size of the second regions B is too small, the barrier layers formed in the third regions C may have a weak barrier function on conductive plugs when subsequently forming the conductive plugs on the source/drain doped regions 203, and the risk that the conductive plugs are in contact with the gate layers 213 in the first regions A and the second regions B to form shorted circuits may still exist. When the range by which the size of the third regions is larger than the size of the second regions B is too large, spaces for subsequently forming the conductive plugs on the source/drain doped regions 203 may be occupied, to influence the performance of the formed conductive plugs.

The area of the third projections may be larger than the area of the second projections, and the second projections and the first projections may be located within the range of the third projections. Therefore, after the barrier layers are formed in the third regions C, when the conductive plugs located on the source-drain doped regions 203 are formed, the barrier layers may be able to limit the position of the conductive plugs, thereby reducing the risk that the conductive plugs are in contact with the gate layers 213 in the first regions A and the second regions B to form shorted circuits and improving the performance of the semiconductor structure.

As shown in FIG. 8, a barrier layer 214 may be formed in each third region C. After forming barrier layers 214, conductive plugs 215 may be formed in the dielectric layer 204. Each conductive plug 215 may be located above one corresponding source/drain doped region 203.

The barrier layers 214 may be made of a material including a dielectric material, and the dielectric material may include one or more of silicon oxide, silicon nitride, silicon oxynitride, silicon oxycarbide, silicon carbide, silicon nitride carbide, silicon oxycarbide, or a combination thereof. In this embodiment, the barrier layers 214 may be made of silicon nitride.

The conductive plugs 215 may be formed by: forming a patterned mask layer (not illustrated) on the dielectric layer 204 and the barrier layers 214, where the patterned mask layer exposes the surface of a portion of the dielectric layer 204 on the source/drain doped regions 203; using the patterned mask layer as a mask to etch the dielectric layer 204 until the surfaces of the source/drain doped regions 203 are exposed, to form openings in the dielectric layer 204 (not illustrated); and forming one conductive plug 215 in each opening.

The material of the barrier layers 214 may have a larger etching selectivity ratio to the material of the dielectric layer 204. Therefore, when the dielectric layer 204 is etched to form the openings, the etching process may have a small etching rate on the barrier layers 214, and the barrier layers 214 may limit the openings correspondingly. When the conductive plugs 215 are formed in the openings, the barrier layers 214 may limit the conductive plugs 215, thereby reducing the risk that the conductive plugs are in contact with the gate layers 213 in the first regions A and the second regions B to form shorted circuits and improving the performance of the semiconductor structure.

The present disclosure also provides a semiconductor structure. As shown in FIG. 8, the semiconductor structure may include:
a substrate;
a dielectric layer 204 on the substrate;
gate openings (not illustrated) in the dielectric layer, where each gate opening may include a first region A and a second region B on the first region A, the first region A may have a first projection on the substrate, the second region B may have a second projection on the substrate, the area of the second projection may be larger than the area of the first projection, and the first projection may be located within the second projection; and
a gate layer 213 in each first region A and one corresponding second region B.

A range by which the size of the second region B along the first direction parallel to the substrate surface is larger than the size of the first region A along the first direction parallel to the substrate surface may be about 1 nm to about 5 nm.

In one embodiment, each gate opening may further include a third region C located on the corresponding second region B. The third region C may have a third projection on the substrate, and the area of the third projection may be larger than the area of the projection of the second region B. The second projection and the first projection may be located within the range of the third projection.

In one embodiment, the semiconductor structure may further include a barrier layer 214 in each third region C.

In one embodiment, a range by which the size of the third region C in the first direction parallel to the substrate surface is larger than the size of the second region B in the first direction parallel to the substrate surface may be about 1 nm to 5 nm.

In one embodiment, barrier layers 214 may be made of a material including a dielectric material, and the dielectric material may include silicon nitride.

In one embodiment, the semiconductor structure may further include: a gate dielectric layer 209 on the sidewall surfaces and bottom surfaces of each first region A, and a work function layer 210 located on the gate dielectric layer 209. Each gate layer 213 may be located on one corresponding work function layer 210.

In one embodiment, the semiconductor structure may further include: source/drain doped regions 203 located in the substrate on two sides of each gate layer 213.

In one embodiment, the substrate may include a base 200 and fin structures 201 located on the base 200. The gate openings may expose a portion of the top surfaces and sidewall surfaces of the fin structures 201. The gate layers 213 may cross the fin structures 201, and the first direction may be the extending direction of the fin structures 201.

In one embodiment, the top surfaces of the first regions A may be higher than or flush with the top surfaces of the fin structures 201.

In one embodiment, the gate layers 213 may be made of a material including metal, and the metal may include tungsten.

In the present disclosure, the semiconductor structure may include gate openings (not illustrated) in the dielectric layer 204. Each gate opening may include a first region A and a second region B on the first region A. The first region A may have a first projection on the substrate and the second region B may have a second projection on the substrate. The area of the second projection may be larger than the area of the first projection, and the first projection may be located within the second projection. Therefore, when forming the gate layers 213 in the first regions A and the second regions B, the material of the gate layers 213 may be easily filled into the first region, such that the formed gate layers 213 may have a dense structure and the reliability of the semiconductor structure may be improved.

Further, each gate opening may further include a third region C located on the corresponding second region B. The third region C may have a third projection on the substrate, and the area of the third projection may be larger than the area of the projection of the second region B. The second projection and the first projection may be located within the range of the third projection. After the barrier layers are formed in the third regions C, when the conductive plugs located on the source-drain doped regions 203 are formed, the barrier layers may be able to limit the position of the conductive plugs, thereby reducing the risk that the conductive plugs are in contact with the gate layers 213 in the first regions A and the second regions B to form shorted circuits and improving the performance of the semiconductor structure.

The embodiments disclosed herein are exemplary only. Other applications, advantages, alternations, modifications, or equivalents to the disclosed embodiments are obvious to those skilled in the art and are intended to be encompassed within the scope of the present disclosure.

1. A semiconductor structure, comprising:
a substrate; and
a dielectric layer on the substrate, the dielectric layer containing gate openings,
wherein:
each gate opening includes a first region and a second region on the first region, the first region has a first projection on the substrate, the second region has a second projection on the substrate, an area of the second projection is larger than an area of the first projection, and the first projection is located within the second projection; and
a gate layer in each first region and one corresponding second region.

2. The semiconductor structure according to claim 1, wherein:
a range by which a size of the second region in a first direction parallel to a surface of the substrate is larger than a size of the first region in the first direction parallel to the surface of the substrate is about 1-5 nm.

3. The semiconductor structure according to claim 1, wherein:
the gate opening further includes a third region on the second region, the third region has a third projection on the substrate, an area of the third projection is larger than the area of the second projection, and the second projection and the first projection are located within the third projection.

4. The semiconductor structure according to claim 3, wherein:
a range by which a size of the third region in the first direction parallel to the surface of the substrate is larger than the size of the second region in the first direction parallel to the surface of the substrate is about 1-5 nm.

5. The semiconductor structure according to claim 3, further comprising:
a barrier layer in each third region.

6. The semiconductor structure according to claim 5, wherein:
the barrier layer is made of a material including a dielectric material, and the dielectric material includes silicon nitride.

7. The semiconductor structure according to claim 1, further comprising:
a gate dielectric layer on sidewall surfaces and bottom surfaces of each first region, and a work function layer on the gate dielectric layer, wherein the gate layer is located on the work function layer.

8. The semiconductor structure according to claim 1, further comprising:
source/drain doped layers in the substrate at two sides of each gate layer.

9. The semiconductor structure according to claim 2, wherein:
the substrate includes a base substrate and fin structures on the base substrate;
the gate openings expose a portion of top surfaces and sidewall surfaces of the fin structures;
the gate layers cross the fin structures; and
the first direction is an extending direction of the fin structures.

10. The semiconductor structure according to claim 9, wherein:
a top surface of the first region is higher than or flush with the top surfaces of the fin structures.

11. (canceled)

12. A method for forming a semiconductor structure, comprising:
providing a substrate;
forming dummy gate structures on the substrate;
forming a dielectric layer on sidewalls of the dummy gate structures;
removing the dummy gate structures to form initial gate openings, wherein: each initial gate opening includes a first region and an initial second region on the first region, and the first region has a first projection on the substrate;
removing a portion of the dielectric layer on sidewalls of each second region to form a gate opening, wherein: the gate opening includes the first region and a second region on the first region, the first region has a first projection on the substrate, the second region has a second projection on the substrate, an area of the second projection is larger than an area of the first projection, and the first projection is located within the second projection; and
forming an initial gate layer in each gate opening.

13. (canceled)

14. The method for forming the semiconductor structure according to claim 12, wherein the second region is formed by:
forming a sacrificial layer in each first region; using sacrificial layer as a mask to etch the dielectric layer on the sidewalls of the initial second region, to form the second region; and after forming the second region, removing the sacrificial layer.

15. The method for forming the semiconductor structure according to claim 14, wherein the sacrificial layer is formed by:
forming a sacrificial material layer in the initial gate openings and on the dielectric layer; and etching back the sacrificial material layer until exposing the initial second regions, to form one sacrificial layer in each first region.

16. The method for forming the semiconductor structure according to claim 14, wherein:
the sacrificial layer is made of an organic material and the organic material includes amorphous silicon or photoresist.

17. The method for forming the semiconductor structure according to claim 14, wherein:
the dielectric layer on the sidewalls of the initial second region is etched by an isotropic dry etching method.

18. The method for forming the semiconductor structure according to claim 14, before forming the sacrificial layer in the first region, further comprising:
forming an initial gate dielectric layer on the sidewall surfaces and the bottom surface of the initial gate opening and an initial work function layer on the initial gate dielectric layer, wherein the sacrificial layer is located on the initial work function layer.

19. The method for forming the semiconductor structure according to claim 18, before using the sacrificial layer as the mask to etch the dielectric layer on the sidewalls of the initial second region, further comprising:
using the sacrificial layer as a mask to remove the initial gate dielectric layer and the initial function layer on the sidewalls of the initial second region, to form the gate dielectric layer and the work function layer on the sidewall surfaces and the bottom surfaces of the first region, wherein the second region exposes the top surface of the gate dielectric layer and the top surface of the work function layer.

20. The method for forming the semiconductor structure according to claim 19, wherein:
the initial gate dielectric layer and the initial function layer on the sidewalls of the initial second region are removed by a wet etching method.

21. The method for forming the semiconductor structure according to claim 12, wherein:
a depth-to-width aspect ratio of each initial gate opening is about 3˜6.

22. (canceled)

23. (canceled)

24. (canceled)

25. The method for forming the semiconductor structure according to claim 24, wherein each gate opening further includes a third region on the corresponding second region, and the third region is formed by:
removing a portion of the initial gate layer to form the gate layer and transition third regions in the dielectric layer, wherein the sidewalls of the transition third regions expose the dielectric layer; and etching the dielectric layer exposed by the sidewalls of the transition third regions to form third regions, wherein: each third region has a third projection on the substrate, an area of the third projection is larger than the area of the second projection, and the second projection and the first projection are located within the third projection.

26. (canceled)

27. (canceled)

28. (canceled)

29. (canceled)

30. (canceled)

31. (canceled)

32. (canceled)
